(19) United States
(12) Patent Application Publication
(10) Pub. No.: US 2023/0340187 A1
(43) Pub. Date: Oct. 26, 2023

(54) METHOD FOR PRODUCING CONDUCTIVE PEDOT:PSS PARTICLES

(71) Applicant: RHEINISCH-WESTFÄLISCHE TECHNISCHE HOCHSCHULE (RWTH) AACHEN, Aachen (DE)

(72) Inventors: Sebastian Bernhard RAUER, Aachen (DE); Daniel Josef BELL, Alsdorf (DE); Matthias WESSLING, Aachen (DE)

(21) Appl. No.: 18/041,237

(22) PCT Filed: Aug. 10, 2021
(86) PCT No.: PCT/EP2021/072276

§ 371 Date: Feb. 10, 2023

(30) Foreign Application Priority Data
Aug. 10, 2020 (DE) 10 2020 121 036.1

(51) Int. Cl. C08G 61/12

(52) U.S. Cl. CPC C08G 61/126; C08G 2261/3223; C08G 2261/962; C08G 2261/794

(57) ABSTRACT

The present invention relates to a process for preparing poly(3,4-ethylenedioxythiophene):polystyrenesulfonate (PEDOT:PSS) particles at least comprising the steps:
a) providing a mixture comprising poly(3,4-ethylenedioxythiophene) and polystyrene sulfonate in a solvent at least comprising water;
b) forming one or more PEDOT:PSS droplets by introducing the mixture from process step a) into an organic solvent A, wherein the aqueous PEDOT:PSS mixture forms the droplet interior and the organic solvent A forms the droplet exterior;
c) contacting the PEDOT:PSS droplets obtained from process step b) with a coagulating solution comprising a curing agent and at least one further solvent B, the density of the coagulating solution being greater than the density of the organic solvent A and less than the density of the aqueous poly(3,4-ethylenedioxythiophene) and polystyrene sulfonate mixture; with curing of the PEDOT:PSS droplets to PEDOT:PSS particles. Furthermore, the present invention discloses spherical PEDOT:PSS particles without further mechanically solidifying substances and the use of the particles, for example, as cell culture microcarriers or suspension electrodes.

### The present invention relates to a process for preparing poly(3,4-ethylenedioxythiophene):polystyrenesulfonate (PEDOT:PSS) particles at least comprising the steps:

a) providing a mixture comprising poly(3,4-ethylenedioxythiophene) and polystyrene sulfonate in a solvent at least comprising water;
b) forming one or more PEDOT:PSS droplets by introducing the mixture from process step a) into an organic solvent A, wherein the aqueous PEDOT:PSS mixture forms the droplet interior and the organic solvent A forms the droplet exterior;
c) contacting the PEDOT:PSS droplets obtained from process step b) with a coagulating solution comprising a curing agent and at least one further solvent B, the density of the coagulating solution being greater than the density of the organic solvent A and less than the density of the aqueous poly(3,4-ethylenedioxythiophene) and polystyrene sulfonate mixture; with curing of the PEDOT:PSS droplets to PEDOT:PSS particles. Furthermore, the present invention discloses spherical PEDOT:PSS particles without further mechanically solidifying substances and the use of the particles, for example, as cell culture microcarriers or suspension electrodes.

In many industries, for example the food, cosmetics or pharmaceutical industries, large quantities of complex biological substances are required. Usually, these substances are produced mostly in stirred tank reactors using cell cultures. Since most vertebrate cells are adherent cells, i.e. dependent on substrates for growth and proliferation, biocompatible carrier particles are usually added to the culture medium. Poly(3,4-ethylenedioxythiophene):polystyrenesulfonate (PEDOT:PSS) particles are the preferred choice here because the dimensions of these particles is in the correct micrometer size range, the surface structure favors anchoring of the cells to the particle surface, the particle density allows suspension of the particles in the stirred tank reactor at low energy input, and the particles are also biocompatible. PEDOT:PSS particles also offer a very high surface-to-volume ratio due to their specific porosity, which provides the basis for efficient large-scale production of biological substances. Furthermore, PEDOT:PSS as a material system also exhibits special electrical properties. The particles can provide very fast charge/discharge kinetics and high energy and power densities because the electrical charge is stored not only in the electronic bilayer but also within the polymer matrix. These basic properties mean that the particles also represent promising substrates in energy storage and energy conversion technology.

To date, filled or porous PEDOT:PSS particles can only be produced in combination with a composite or carrier material, which gives the particles an intrinsically missing, mechanically supporting as well as shaping property. For the synthesis of these stabilized particles, complex, multi-step process steps are necessary, which offer only insufficient prerequisites for efficient scale-up and, in the case of hybrid particles, lead to a deterioration of the electrochemical properties of the particles due to the electrically inactive additive material. In addition, there are no processes and, accordingly, no commercially available microcarriers that are produced on the basis of only one, completely synthetic hydrogel. Some approaches to PEDOT:PSS microparticles can be found in the patent literature.

For example, EP 28 311 83 B1 describes a composite particle comprising: a single spherical core comprising at least one inorganic oxide; and a polymer layer disposed on and delimiting the spherical core, the polymer layer comprising a cationic polymer and an anionic polymer.

Furthermore, EP 01 953 81 B1 discloses a composite of porous materials and electrically conductive polymers, wherein the surfaces of the pores are first coated with a layer of an electrically conductive polymer obtained by treating the monomers with an oxidizing agent, and a layer of an electrically conductive polymer obtained by anodic oxidation of the monomers is applied thereon.

In another patent document, CN 110 233 061 A, a manufacturing method of a porous flexible PEDOT: PSS film with high conductivity is disclosed. According to the method, polystyrene nanospheres are used as matrices; PEDOT:PSS dispersion liquid and the polystyrene nanospheres are mixed in situ; A porous PEDOT:PSS film is obtained by vacuum suction filtration. The conductivity of the film is optimized by solvent post-treatment. The produced PEDOT:PSS film has porous structure, shows excellent electrochemical properties such as relatively high conductivity, high charge discharge stability, high rate performance and the like, can be used for high performance film electrode or high performance film capacitor.

Such solutions, known from the prior art, may offer further potential for improvement, especially with regard to the simplicity of the manufacturing process, the reproducibility as well as the uniformity of the particles that can be produced via the process.

It is therefore the task of the present invention to at least partially overcome the disadvantages known from the prior art. In particular, it is the task of the present invention to disclose a simple and reproducible manufacturing process, which is easily up-scalable and provides highly accurately defined PEDOT-PSS particles within short process times. Furthermore, it is the task of the present invention to provide PEDOT:PSS particles which exhibit a very uniform shape and size distribution without further polymer stabilization.

The task is solved by the features of the respective independent claims, directed to the method according to the invention, the particles according to the invention and the use of the particles according to the invention. Preferred embodiments of the invention are described in the dependent claims, in the description or in the figures, whereby further features described or shown in the dependent claims or in the description or in the figures may individually or in any combination constitute an object of the invention if the context does not clearly indicate the contrary.

According to the invention, the problem is solved by a process for preparing poly(3,4-ethylenedioxythiophene):polystyrenesulfonate (PEDOT:PSS) particles at least comprising the steps:
a) providing a mixture comprising poly(3,4-ethylenedioxythiophene) and polystyrene sulfonate in a solvent at least comprising water;
b) forming one or more PEDOT:PSS droplets by introducing the mixture from process step a) into an organic solvent A, wherein the aqueous PEDOT:PSS mixture forms the droplet interior and the organic solvent A forms the droplet exterior;
c) contacting the PEDOT:PSS droplets obtained from process step b) with a coagulating solution comprising a curing agent and at least one further solvent B, the density of the coagulating solution being greater than the density of the organic solvent A and less than the density of the aqueous poly(3,4-ethylenedioxythiophene) and polystyrene sulfonate mixture; with curing of the PEDOT:PSS droplets to PEDOT:PSS particles.

Surprisingly, it was found that above given process allows flexible preparation of full and porous PEDOT:PSS particles, with the particles being mechanically stable even without further composite or supporting substances. The absence of further mechanically stabilizing substances preserves the native properties of the polymer system in their entirety and avoids unwanted incompatibilities in the application. The 2-step process according to the invention allows cost-effective production and offers simple up-scaling possibilities. Different particle sizes and densities can be flexibly achieved, with highly reproducible, preferably round geometries being obtainable via the process. Another advantage is that a very homogeneous and narrow particle size distribution can be obtained. After the reaction, the PEDOT:PSS polymer complex represents a biocompatible, porous hydrogel with steric and mechanical properties comparable to an extracellular matrix and thus forms a good basis for use in cell culture applications. The lack of addition of further, stabilizing polymers can also have a positive effect on the electrical properties of the particles.

The process according to the invention is a process for the preparation of poly(3,4-ethylenedioxythiophene):polystyrene sulfonate (PEDOT:PSS) particles. The process according to the invention provides PEDOT:PSS particles which consist of or comprise a PEDOT-PSS matrix. In this respect, the particles may consist of or comprise only these two monomers. Preferably, the matrix may comprise only PEDOT and PSS. The particles have either a closed, dense surface, or else a porous structure, in which case pores are present in the particle interior and/or on the particle surface. The pores can also provide a continuous diffusion path through individual particles. The particle density can be adjusted, for example, via the solids content of the PEDOT-PSS solution used, whereby a broad concentration range can be processed via the method. Preferably, the solids content of the aqueous PEDOT:PSS solution can be greater than or equal to 0.5 wt % and less than or equal to 10 wt %, further preferably greater than or equal to 1.0 wt % and less than or equal to 5.0 wt %. Even with relatively small solids contents, sufficiently mechanically dimensionally stable particles can be produced via the presented process. The degree of porosity of the particles can be varied over a wide range via the proportion of further solvents in the aqueous solution and can preferably be greater than or equal to 0% by volume and less than or equal to 95% by volume, further preferably greater than or equal to 15% by volume and less than or equal to 60% by volume.

In process step a), a mixture comprising poly(3,4-ethylenedioxythiophene) and polystyrenesulfonate is prepared in a solvent comprising at least water. The starting material of the preparation is an aqueous PEDOT and PSS mixture in which the polymer complexes of positively charged PEDOT and negatively charged PSS are dispersed. In addition to water, this aqueous starting solution can also contain other solvents or dispersants, whereby the porosity of the particles, for example, can be adjusted via the proportion and type of solvent. The term “solvent” is used here not in the physical sense of producing a true “solution”, but in the sense that these substances normally fall under the category of a liquid solvent. If “only” water is used as a solvent or dispersant, non-porous particles will result. For example, PEDOT:PSS may be present in a molar ratio greater than or equal to 1:6 and less than or equal to 6:1. For example, the weight concentration of PEDOT:PSS in the aqueous mixture may be greater than or equal to 1 wt % and less than or equal to 10 wt %.

In process step b), one or more PEDOT:PSS droplets are formed by introducing the mixture from process step a) into an organic solvent A, with the aqueous PEDOT:PSS mixture forming the droplet interior and the organic solvent A forming the droplet exterior. The aqueous PEDOT:PSS dispersion is emulsified in an organic solvent to form a water (PEDOT:PSS)-in-solvent A emulsion. The aqueous PEDOT:PSS thus forms the inner phase and the organic solvent the outer phase. Thus, the organic solvent A may not be completely miscible with water. Preferably, the organic solvent A may have a miscibility of water of less than or equal to 10 g/l, further preferably of less than or equal to 5 g/l at 20° C. Emulsification can be carried out without the further use of emulsifiers, purely by mechanical means. Thus, the use of a mechanical stirrer, a Turrax or a microfluidic setup with T-branch geometry may be suitable to obtain an emulsion with a droplet size as uniform as possible. However, the emulsion can also be obtained via ultrasonic treatment. The emulsion does not have to be stable over long periods of time. Organic solvents A that are stable to the chemical conditions in the further course of the process are suitable. For example, these can be medium-chain hydrocarbons without further reactive groups. For example, C4-C10 hydrocarbons or alkanes can be used. Furthermore, it is also possible to use organic solvents consisting of hydrocarbons and one or more further functional groups. For example, medium-chain alcohols, such as C5-C10 alcohols, can also be used as solvent A.

Process step b) can be carried out, for example, within a co-axial droplet separation process in which the emulsion droplets are separated from the nozzle by a continuous phase. The PEDOT:PSS is thereby converted into a spherical form. Here, the continuous phase from solvent A completely envelops the PEDOT:PSS emulsion and serves as a shell to retard the curing process. The generation of monodisperse PEDOT:PSS emulsion droplets in the continuous phase can be carried out, for example, by means of one or more cannulas inserted concentrically into a slightly kinked tube. In this case, the continuous phase from solvent A is fed through the tube and the PEDOT:PSS emulsion is fed via the cannula. The protective sleeve consisting of the continuous phase of solvent A prevents the PEDOT:PSS emulsion from curing inside the nozzle and blocking the apparatus. The process cannot be carried out without the retarding effect of the droplet exterior consisting of solvent A as the continuous phase. Slot dies or dies of other design can also be used to form other molded geometries. By selecting the extrusion quantity and speed, it is also possible to produce more or less elongated molded bodies, such as fibers.

In process step c), the PEDOT:PSS droplets obtained from process step b) are contacted with a coagulating solution comprising a curing agent and at least one further solvent B. The PEDOT:PSS droplets are then removed from the curing agent. Due to the mechanical energy input, an emulsion with PEDOT:PSS droplets has been obtained, at least temporarily, from the organic solvent A and the aqueous PEDOT:PSS solution, the droplets being protected by an outer solvent A phase. These enveloped droplets are now transferred to a coagulating solution. The transfer of the enveloped droplets into the coagulation solution can be done directly from the tubing which was used, for example, for feeding the continuous phase in process step b). The protective envelope consisting of the continuous phase is then rapidly separated from the PEDOT:PSS emulsion droplet via the density difference between the coagulation bath and the continuous phase, whereby the emulsion of aqueous PEDOT:PSS solution meets the coagulation solution, which comprises at least one further solvent B and a curing agent. Preferably, the curing agent may be homogeneously dissolved or dispersed in the organic solvent B. The curing agent can be any substance capable of dissolving PSS from the PEDOT-PSS polymer complex and causing crystallization of the PEDOT. Preferably, the curing agent may be present dissolved in the organic solvent B. Possible curing agents may be selected, for example, from the group consisting of sulfuric acid, ionic liquids, highly concentrated salt solutions or mixtures of at least two curing agents from this list. Suitable organic solvents B may be selected, for example, from the group consisting of branched or unbranched C1-C10 alcohols or water or mixtures of at least two solvents thereof. Suitable organic solvents must have a density less than PEDOT:PSS to allow separation of the protective solvent A shell and, at best, should have a high solubility with respect to solvent A.

The density of the coagulating solution is greater than the density of organic solvent A and less than the density of the aqueous PEDOT:PSS mixture. Thus, according to the invention, the density of the coagulating solution of organic solvent B and curing agent must be greater than the density of organic solvent A, as well as greater than the density of further solvents in cases where the aqueous PEDOT:PSS mixture also contains further solvents. This relation of the different solvents can be controlled, for example, by the density of the coagulating solution. In principle, the density of the coagulating solution can be influenced by two different parameters. First, of course, the density of the coagulating solution can result from the choice of the solvent B itself. On the other hand, the density of the solvent B itself can be further adjusted by the choice of the concentration of the curing agent in the solvent B. The densities of organic solvent A and organic solvent B including curing agent are of course compared under the same temperature conditions to obtain the above relation. If the coagulating solution contains other density-relevant admixtures or substances in addition to the curing agent and solvent B, these are included in the density of the coagulating solution. The changes in the density of the coagulating solution due to the dripping of the emulsion are not taken into account, since the volume of the coagulating solution is considered to be very large compared to the volume of the dripped solution. The density of the coagulating solution of solvent B and curing agent must also be smaller compared to the aqueous PEDOT:PSS mixture. Preferably, the density differences between aqueous PEDOT:PSS mixture, organic solvent A and coagulation bath comprising organic solvent B+ curing agent can be greater than or equal to 5%, further preferably greater than or equal to 10%. Within these density differences, the protective layer of the PEDOT:PSS droplets consisting of organic solvent A can be removed very quickly and very uniform particles can be produced. The absolute density difference is what counts, and as a function of the sign of the density difference, the solution can be introduced into the coagulation bath once from above or from below. The separation of the protective shell consisting of solvent A is further aided by the solubility of solvent A in solvent B.

By introducing the PEDOT:PSS emulsion enveloped in solvent A into the coagulating solution, the PEDOT:PSS droplets are cured into PEDOT:PSS particles. The density relations given above allow the shell around the PEDOT:PSS droplets to be slowly separated from the aqueous PEDOT:PSS mixture due to the density difference as well as the solubility in solvent B. The aqueous PEDOT:PSS mixture is then coagulated. The protection of the internal aqueous PEDOT:PSS droplets by the organic solvent A is removed and the curing of the PEDOT:PSS complex in the coagulation bath by the curing agent begins. The curing agent leads to partial crystallization of the PEDOT:PSS droplet, with solvent B simultaneously leading to non-solvent-induced phase separation. Thus, the PEDOT:PSS droplet completely hardens to the particle within a short time due to the interaction with the coagulation bath. In the case of porous particles, additional 1 to 40 μm emulsion droplets consisting of a solvent, for example solvent A, may still form within the PEDOT:PSS particle, forming the porosity of the particle during the curing process in the coagulation bath. These remaining droplets of organic solvent A, which are still present in the particles, can further serve as a scaffold for the formation of a spherical shape, in addition to creating particle porosity. If other solvents that can be separated out by density differences are present in the aqueous PEDOT:PSS mixture, they provide for the formation of a cured porosity. Since the organic solvent B can also partially be a solvent for the organic solvent A, the structure not only guarantees sufficient particle consolidation, but also liberation of the particle pores from the further solvent.

In a preferred embodiment of the process, the organic solvent A may be selected from the group consisting of branched or unbranched C5-C10 alkanes, branched or unbranched C5-C10 alcohols or mixtures of at least two solvents thereof. To obtain a sufficiently stable emulsion of the aqueous PEDOT:PSS mixture in organic solvent A, the above-mentioned solvent group has proved to be particularly suitable. Sufficiently homogeneous and small droplets can be produced with very low shear forces, which do not exhibit too high solubility for water. Without being bound by theory, it may also be advantageous that the surface porosity of the particles is particularly positively influenced by this solvent selection. Furthermore, another advantage may be that in the event that the aqueous PEDOT:PSS mixture has further solvents to form a porosity, the liberation of the pores from the solvent is particularly fast due to a possible good solubility in solvent B.

Within a preferred aspect of the process, solvent B may further be selected from the group consisting of branched or unbranched C1-C5 alcohols or mixtures of at least two substances thereof. This group of solvents B in the coagulation bath has been found to be sufficiently stable for a number of different curing agents. Furthermore, these solvents exhibit sufficiently high solubility for the most important curing agents, resulting in a homogeneous coagulation bath. Another advantage of this group is that there is a preferential interaction with any solvent A emulsified in the droplet. The solvent A is dissolved out within an optimum time window, so that sufficient time is available to stabilize the drop shape during curing and to completely separate the surrounding organic phase from the particle interior within the same process step.

In a further preferred embodiment of the process, the solvent A can comprise octanol and the coagulating solution in process step b) can comprise isopropanol as solvent B and sulfuric acid as curing agent. This combination of solvent and curing agent in the various process steps has proved to be particularly advantageous. Particularly stable and homogeneously crosslinked PEDOT:PSS particles result, which can also be characterized by a particularly uniform porosity. Without being bound by theory, the synergistic advantages result from a particularly advantageous solubility of solvents A and B within and with each other. The droplet freed from the octanol shell comes into contact with the coagulation mixture and cures completely by interaction with the sulfuric acid as curing agent. The octanol droplets, which are still present in emulsified form in the aqueous PEDOT:PSS solution or dispersion, can thereby act in particular as a scaffold for the formation of a spherical shape and ensure the formation of controlled porosity. Since isopropanol is a partial solvent for octanol and possibly the further emulsified solvent, the coagulation mixture guarantees not only particle curing by removal of the droplet shell, but also controlled liberation of the pores from the further solvent. Preferably, 1-octanol can be used as the octanol. The latter can contribute to the formation of particularly uniform droplets.

In a preferred aspect of the process, the weight ratio of curing agent and solvent B in the coagulating solution, expressed as weight of curing agent divided by weight of solvent B, may be greater than or equal to 0.005 and less than or equal to 0.2. For efficient and controlled curing while obtaining particularly uniform, spherical PEDOT:PSS particles, the above ratio has been found to be particularly suitable. On the one hand, the rate of detachment of the encapsulating solvent A, if necessary the removal of further solvent from the aqueous PEDOT:PSS mixture, and the subsequent contact time with the curing agent are subjected to a dynamic equilibrium which, based on kinetic considerations, can be used in particular to form more spherical particles. Thus, higher levels of curing agent can contribute to the formation of more non-round particles. Lower levels of curing agent may tend to contribute to only insufficient solidification of the PEDOT:PSS droplets or to require too long contact times in the coagulation bath. In a preferred embodiment, the lower limit of the range may be 0.01.

In a further preferred characteristic of the process, the PEDOT:PSS mixture in process step a) can have no further mechanically strengthening substances. Surprisingly, it has been found that mechanically very stable particles are obtainable via the process according to the invention which, in addition to PEDOT and PSS, are free of further mechanical strengthening substances in the sense of mechanical stabilizers. Commonly used solidifying substances are selected from the group of polymeric admixtures or purely supporting or shaping solids. These substances are also known to those skilled in the art under the term “template particles”. In the field of polymeric admixtures, this means that the PEDOT:PSS solution used can, for example, be free of further monomers or polymers. Polymeric constituents can be, for example, substances that have a molecular weight greater than or equal to 2,000 g/mol, and these substances can be present in the aqueous PEDOT:PSS solution or can be formed in the course of production. Furthermore, the PEDOT:PSS particles may be free of other mechanically solidifying substances such as plastic microparticles e.g. polystyrene microparticles, silica microparticles or salt crystals such as calcium carbonate. In this respect, the group of solidifying substances of non-polymeric character comprises at least salt crystals, plastic microparticles, quartz microparticles or mixtures thereof. In addition, the PEDOT:PSS solution used may nevertheless contain other low-molecular substances which can, for example, influence or adapt the electrical properties of the PEDOT:PSS network.

Within a further preferred aspect of the process, the aqueous PEDOT:PSS mixture in process step a) may comprise an organic solvent A as a further solvent component in addition to water. To form a controlled porosity and to form mechanically stable particles, the use of a solvent A to generate an emulsion of solvent A in aqueous PEDOT:PSS solution has been found to be simple and efficient. The number of substances involved is kept low and separation from the emulsion is rapid and largely complete. Furthermore, the volume fraction of solvent A in the total volume of the aqueous PEDOT:PSS mixture can be greater than or equal to 15% and less than or equal to 60%. Within these volume fractions of organic solvent A in the aqueous mixture, mechanically very stable particles can be obtained within very short process times, which also exhibit a very uniform pore size distribution. Smaller proportions can be disadvantageous, since due to the only isolated solvent A droplets, no cross-linked porosity can be formed, but only isolated defects in the particle. Higher proportions can contribute to only insufficient mechanical stability of the particles.

Furthermore, poly(3,4-ethylenedioxythiophene) polystyrenesulfonate particles are according to the invention, whereby the particles are formed spherically and do not contain any further mechanically solidifying substances besides PEDOT:PSS. Even without further mechanically solidifying admixtures in the reactant or in the formed particle, mechanically extremely stable PEDOT:PSS particles can be obtained, which are also characterized by a particularly uniform, spherical shape. The solidifying substances are defined above in connection with the process according to the invention. Polymeric constituents can, for example, be substances which have a molecular weight of greater than or equal to 2,000 g/mol, and these substances can be present in the aqueous PEDOT:PSS solution or can be formed in the course of production. In addition to the particular embodiment in the form of spheres, the particles may further have a particularly narrow spherical size distribution. The spherical configuration can, for example, be mathematically detected by the sphericity of the particles, which, according to the invention, can be greater than or equal to 0.91. This sphericity range can be determined microscopically and generally describes the ratio of the surface area of a sphere of the same volume to the surface area of the body present. An average value of at least 20 individual particles can be used for the determination. Further, the sphericity of the particles may be greater than or equal to 0.95 and less than or equal to 1. Furthermore, the particles may be free of emulsifiers, wetting agents or other surface-active substances that are commonly used to produce emulsions.

Furthermore, according to the invention, PEDOT:PSS particles are produced by the process according to the invention. In addition to the size distribution, the mechanical stability and the porosity, further properties can be determined via the process according to the invention, which differ from the properties of processes produced according to the state of the art. For the further advantages of these particles obtainable via the process according to the invention, explicit reference is made to the advantages mentioned in connection with the process according to the invention.

Within a further preferred aspect of the particles, the particles may have a modulus of elasticity greater than or equal to 0.05 MPa and less than or equal to 15 MPa. The mechanical properties of the particles according to the invention can also be adjusted over a wide range without the addition of further mechanically active substances. In addition to the porosity of the particles, the crystallinity in particular can have a major influence on the modulus of elasticity. The degree of crystallization of the individual chain segments can be influenced, for example, by the acid-catalyst concentration, whereby the acid concentration influences the molecular arrangement of the individual chain segments among themselves. The elastic modulus (Young's modulus) of the particles can be determined via tensile tests on strip-shaped particles. The modulus of elasticity is determined on particles in fiber form in the wet state, as described in the examples.

According to a preferred characteristic of the particles, the particle can be at least partially crystalline with Bragg reflections in an XRD spectrum at 4.3 (+−0.2) nm⁻¹ and 18.4 (+−0.2) nm⁻¹. Mechanically very stable particles can be obtained via the process according to the invention, which are also characterized in particular by a high degree of crystallization. In particular, the degree of crystallization can lead to particles with a high elastic modulus. The crystalline particles are characterized by a solid-state powder X-ray diffractogram, which shows visible reflections at positions indicated above. Furthermore, the diffractogram may show another peak at 8.6 nm⁻¹. For example, the ratio of peak heights at 4.3 and 8.6 nm⁻¹ may be 1:2. These reflections can be attributed to the lamellar arrangement of the individual chains with a periodicity of 1.5 nm in the particle. The reflection at about 18 nm⁻¹ results highly likely from regularly arranged π-π-stacks of adjacent PEDOT chains. In contrast, less crystalline particles, for example produced with low acid concentrations in the coagulation bath, show a small size of the crystalline regions with only 1.8 nm. In these particles with low crystallinity, no distinct lamellar structure can be detected via defined Bragg reflections.

In a further preferred embodiment of the particles, the surface of the particle can have a zeta potential of less than or equal to 0 mV. Using the process according to the invention, particularly suitable, mechanically stable particles can be obtained without the addition of further polymeric framework substances or mechanically effective fillers, which are also characterized by a favorable, negative zeta potential. This negative surface charge can contribute to improved functionalization of the particle surfaces, particularly in the field of cell cultures. The electrically negative functionalization of the surface can be used in several steps, for example, to apply a positive charge and thus subsequently obtain improved cell adhesion. Thus, more biocompatible particles may result, which show faster adhesion and improved proliferation of cells on and in the particle. The zeta potential can be determined, for example, by a combined optical/electrical measurement that measures the migration speed of the particles as a function of an applied voltage. The influence of the individual particle geometries on the measurement result is known to the skilled person and these effects can be calculated out. Preferably, the surface charge can be less than or equal to −10 mV, further preferably less than or equal to −15 mV. The lower limit of the potential can be, for example, −75 mV, further preferably −50 mV.

In a preferred embodiment of the particles, the particles may have a size distribution with a D50 quantile in a range greater than or equal to 10 μm and less than or equal to 1,000 μm. The particles obtainable via the process according to the invention can be produced over a wide size range via the choice of nozzle size as well as the flow rate ratio between continuous phase and aqueous PEDOT:PSS dispersion. Very homogeneous size distributions result, which can have a polydispersity index of less than or equal to 1.2, further preferably of less than or equal to 1.1. The polydispersity index can be determined by microscopic measurements.

In a preferred embodiment, the particles may be porous and have a porosity greater than 0 volume % and less than or equal to 95 volume %. It has been shown that a wide range of particle porosities is accessible by means of the process according to the invention, and it is particularly surprising that even under high porosities the particles show sufficient mechanical strength, even in the absence of further stabilizing substances. Particles can thus be provided which exhibit very high specific surface areas and which do not contain, for example, electrically interfering or inactive substances. The particle porosity can be determined, for example, by microscopy on freeze-dried particles.

Furthermore, according to the invention, the use of the particles according to the invention may be selected from the group consisting of cell culture microcarriers, suspension electrodes, switchable redox absorber material, catalyst supports or combinations thereof. Due to the uniformity in size distribution, the controllable porosity, and the fact that no other mechanically solidifying and/or surface active substances need to be present on or in the particles besides PEDOT:PSS, the particles are suitable for a number of different applications. In the case of use as a suspension electrode, the use of the particles results in a multiphase material system, which has the particles as the active charge-storing component. These can be present suspended in an ionic solution or an electrolyte. Gravimetrically, the electrolyte is the main component and contributes to the physical transport of the active material. The internal and surface porosity of the particles according to the invention leads to an improvement of the electrochemical properties, including an improved utilization of the electrical capacity and faster charging and discharging kinetics, whereby the particles according to the invention show a high potential with respect to electrochemical energy storage in the form of supercapacitors or batteries. The PEDOT:PSS particles, which can be flexibly produced via the process according to the invention, are nontoxic and thus compatible with cells and, in addition to high mechanical stability in aqueous systems, also exhibit excellent redox reversibility. The achievable conductivities are, compared to the state-of-the-art polymer particles, higher. Furthermore, as a material system, the PEDOT:PSS particles according to the invention exhibit very fast final charge kinetics, whereby the charge can be stored not only in a superficial, electrical double layer but also within the polymer matrix. The latter results in particular in a high energy and power density of the particles.

Within a preferred aspect of use, the particles can be used as cell culture microcarriers, wherein the surface of the particles is coated with one or more molecules selected from the group consisting of, inter alia, poly-L-lysine, laminin, collagen, fibronectin, vitronectin or mixtures thereof prior to cultivation. The exclusion of other carrier substances in the basic particle structure can result in highly biocompatible carriers which, due to their surface charge, also offer the possibility of subsequent electrostatic functionalization. All extracellular matrix proteins that exhibit an isoelectric point <7 in aqueous solutions can be coated onto the particles. These compounds thus exhibit a negative charge and can thus adhere to poly-L-lysine, for example. Other charged components of the extracellular matrix or else synthetic polyelectrolytes can be bound on the surface, for example. These components can cause a faster and better adhesion, as well as a higher cell division rate.

In another embodiment of use, the surface of the particles may be coated first with poly-Llysine and then with laminin Successive and double coating can contribute to improved biocompatibility of the carriers. Difficult-to-culture cell lines can also be processed under high yields. For coating, the surface of the particles can first be treated with poly-L-lysine. After sufficient absorption of the poly-L-lysine, laminin can then be absorbed onto the applied poly-L-lysine layer in a second step.

### EXAMPLES

### I Structure

The microfluidic co-flow device for the production of spherical PEDOT:PSS particles according to the invention is made of a polyethylene tube with an inner diameter of 0.86 mm, a 30 G disposable cannula and epoxy glue. The tubing is bent at a 45° angle and fixed to a microscopy glass slide with the epoxy glue. The cannula is then inserted into the tubing at the bend. The cannula is finally positioned concentrically in the tube and fixed to the microscopy glass carrier with epoxy glue. Here, the end of the polyethylene tubing facing towards the cannula tip represents the subsequent apparatus exit, while the end facing away from the cannula tip is the entrance for the continuous phase. The male screw cap of the inserted 30 G disposable cannula is then connected to a female-to-female connector, which is connected to another polyethylene tube via a second 30G disposable cannula. This polyethylene tubing is used in the manufacturing process to deliver the pure PEDOT:PSS dispersion (full particles) or the 1-octanol PEDOT:PSS emulsion (porous PEDOT:PSS particles).

II Particle production

To prepare the full PEDOT:PSS particles, a 10 mL disposable syringe is filled with a 1.3 wt % aqueous PEDOT:PSS mixture (Haereus). The drawn up syringe is then connected to the appropriate tubing end of the co-flow apparatus via a 30 G cannula. Another 10 mL disposable syringe is used to draw up 1-octanol as solvent A. This syringe is connected to the tubing end via a 30 G cannula. The two drawn-up syringes are finally fixed in the holders of two separate syringe pumps, which are used to deliver the respective phase. Optimally, the delivery rate of the aqueous PEDOT:PSS base solution can be set to 0.01 mL/min and the delivery rate of the 1-octanol to 0.5 mL/min These values have proven to be particularly favorable for drop formation, since they guarantee a sufficiently large drop spacing in the tube and lead to the desired drop size. For curing, the still liquid PEDOT:PSS droplets together with the surrounding continuous 1-octanol phase are passed over the end of the tubing into a coagulation bath consisting of 5 vol. % sulfuric acid and 95 vol. % isopropanol. The 1-octanol envelope surrounding the PEDOT:PSS drop prevents the PEDOT:PSS from hardening in the cannula and is later gently removed in the coagulation bath via the density difference. With the removal of the 1-octanol shell by detachment in the coagulation bath, the curing process of the PEDOT:PSS droplet begins, which sediments in the coagulation bath due to the higher density. During the curing process, PSS is removed from the PEDOT:PSS polyelectrolyte complex due to complexation with H₊ ions, causing the hydrophobic PEDOT to aggregate and crystallize via π-α interactions. Ultimately, fully cured, pure PEDOT:PSS particles can be picked up at the bottom of the coagulation bath vessel.

For the production of porous PEDOT:PSS particles, the experimental setup remains unchanged. However, instead of a pure aqueous 1.3 wt % PEDOT:PSS solution, a 1-octanol (solvent A) in PEDOT:PSS emulsion is filled into a syringe. The emulsion is then emulsified with a UP200S from Hielscher Ultrasound Technology with 0.5 cycles and an amplitude of 50%, for 1 min. Depending on the desired porosity, the volume ratio of 1.3 wt % PEDOT:PSS solution and the other solvent from group A, for example 1-octanol, in the emulsion can be varied. Particles containing 30 vol.% of 1-octanol in the 1.3 wt.% PEDOT:PSS aqueous solution may be suitable for cell culture experiments.

III Measurement methodology
III.1 XRD measurements

Powder X-ray diffraction spectroscopy (WAXS) was performed using an Empyrean setup from PANalytical. A Cu X-ray tube (line source of 12×0.04 mm 2) provided CuK α-radiation with λ=0.1542 nm. The source and detector moved in the vertical direction around a fixed horizontal sample. After passing a divergence slit of ⅛° and an anti-scattering slit of ¼°, the beam reached the sample in the center of a phi-chi-z table. In the Bragg-Bretano geometry used, the beam was refocused at a secondary divergence slit of ¼°. Finally, the signal was recorded with a pixel detector (256×256 pixels of 55 μm) as a function of the scattering angle 2θ. Then, the peak positions were calculated from q=2π/d=(4π/λ)sin θ, where q is the scattering vector. The detector was used in a scanning geometry that allowed all rows to be used simultaneously. To reduce background, the divergent beam perpendicular to the scattering plane was controlled by a mask of 4 mm, which limits the width of the beam at the sample position to about 10 mm. In addition, the perpendicular divergence was limited by target slits to angles ≤2.3°. For each new measurement, the height of the (powder) sample was optimized. Scans were performed with 20 of the detector axis moving at twice the speed of the θ-axis of the incident beam. The calibration was checked with a Si reference sample. The resolution of the entire setup was determined by measuring a high-quality Si wafer, which yielded a resolution-limited peak with a half-width of 0.026 deg.

III.2 Mechanical measurements

Tensile tests were performed on a custom-built laboratory setup consisting of a micromanipulator linear arm (MM33, Märzhäuser Wetzlar GmbH & Co. KG, Germany), a stepper motor (NEMA 17, Stepperonline), and a high-precision balance (Mettler Toledo, Switzerland). The PEDOT:PSS fibers were fixed on c-shaped cardboard holders with an inner leg spacing of 10 mm The cardboard holders guaranteed a defined initial length of the fibers and prevented elongation before the tensile tests. The immobilized PEDOT:PSS fibers were then soaked in DI water for 10 seconds before the cardboard holder was attached to the linear arm and scale via clamps. Finally, the cardboard legs were separated by a cut and the PEDOT:PSS fibers were stretched to failure at a drawing rate of 0.2 mm/s. Strain and mass were recorded by a self-written Python script.

III.3 Coating with ECM molecules

The adsorption behavior of differently charged polyelectrolytes (PEs) on the surface of PEDOT:PSS particles was investigated using fluorescein isothiocyanate (FITC)-labeled PEs. Positively charged poly-L-lysine (PLL) (15,000-30,000 Da, Sigma Aldrich) and negatively charged polystyrene sulfonate (PSS) (Surflay Nanotec GmbH) with a labeling level of 10% were dissolved in 0.1 M sodium chloride (NaOH) aqueous solutions at a concentration of 1 mg/ml with constant stirring at room temperature overnight. Subsequently, the PEDOT:PSS particles were incubated in the respective PE solutions for 5 days under light-shielding conditions. Finally, the samples were rinsed twice in a 0.1 M NaOH aqueous solution and imaged using a TCS SP8 Falcon confocal microscope (Leica, Germany). For culturing MRC-5 cells, PEDOT:PSS particles were coated layer by layer with PLL and laminin (from human placenta, Sigma Aldrich). Microcarriers were incubated in 0.1 mg/ml PLL solution on a roller device at room temperature for 24 h. Subsequently, the samples were rinsed in Milliq water and incubated in a 40 μg/ml laminin solution on a roller device at 37° C. for an additional 24 h.

III.4 Cell culture

Cell maintenance: L929 mouse fibroblast cells were cultured in Roswell Park Memorial Institute (RPMI) 1640 medium (4500 mg/L glucose, L-glutamine, sodium pyruvate, sodium bicarbonate) (Thermo Fisher Scientific), whereas MRC-5 human embryonic fibroblast cells were cultured in Minimal Essential Medium (MEM) (1000 mg/L glucose, 1× nonessential amino acids, L-glutamine, sodium bicarbonate) (Sigma Aldrich). Both cell culture media were also supplemented with 10% (v/v) fetal bovine serum (FBS) and 1% (v/v) penicillin/streptomycin. Cell lines were maintained at 37° C. in an atmosphere of 5% CO₂ and 95% humidity. Passage numbers were limited to 30 subcultures regardless of cell line.

Cytotoxicity of the particles was evaluated by comparing cell proliferation in fresh medium with cell proliferation in leached medium using a tetrazolium salt-based cell proliferation kit II (XTT) (Roche Diagnostics GmbH) on the fifth and ninth culture days. The leached medium was prepared by incubating low- or high-crystallinity PEDOT:PSS microcarriers in RPMI and MEM media for 5 days at 37° C. at a ratio of 10 particles per 100 μl of medium. The leached medium was collected and stored at 4° C. until use. Cells were seeded in TC-treated microtiter plates (96 wells, Corning Life Sciences) with an L929 seeding concentration of 1,500 cells per well and an MRC-5 seeding concentration of 10,000 cells per well. Cells were then maintained in fresh or leached medium for 9 days, with medium changes every 48 h to ensure adequate nutrient supply. For cell viability analysis, cell holding microplates were washed with PBS (1×) (Lonza, Switzerland) before being exposed to 150 μl of XTT solution for 4 h at 37° C. Subsequently, 100 μl of each sample was transferred to a fresh TC-treated microplate (96 wells) and absorbance was measured at 450 and 630 nm using a microplate reader (Synergy HT, BioTek). Cell viability was determined from the ratio of absorbance values of cells cultured in leached medium to cells cultured in fresh medium (control).

Immunostaining: for morphological assessment, cells were stained for nuclei and F-actin by treating samples with DAPI solution (abcam, UK) for 5 min and phalloidin-iFluor 488 reagent (abcam, UK) for 60 min Prior to staining, all samples were fixed in 4% (v/v) paraformaldehyde (PFA) solution for 15 min, permeabilized in a 0.1% (v/v) Triton X-100 solution for 5 min, and rinsed thoroughly in PBS (1×). Visual analysis of cell viability was performed using a Live/Dead Cell Double Staining Kit (Sigma Aldrich). Cell samples were exposed to sterile PBS (1×) solution containing 0.1% (v/v) calcein-AM and 0.2% (v/v) propidium iodide for 30 min at 37° C.

Further advantages and advantageous embodiments of the objects according to the invention are illustrated by the figures and explained in the following examples. It should be noted that the figures are descriptive only and are not intended to limit the invention in any way.

The figures show:

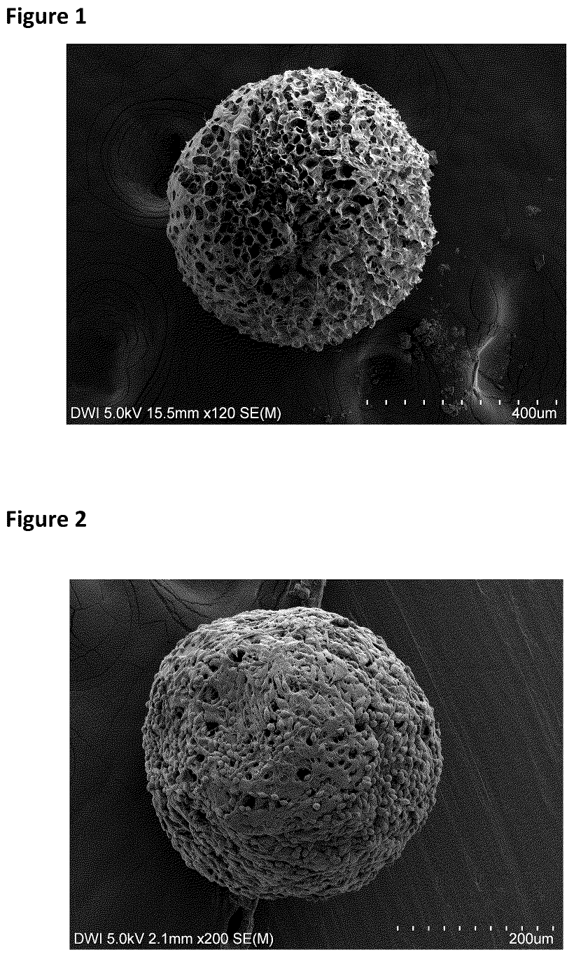

FIG. 1 an FeSEM image of a porous PEDOT:PSS particle prepared according to the invention;

FIG. 2 an FeSEM image of a porous PEDOT:PSS particle with fibroblast colonization prepared according to the invention;

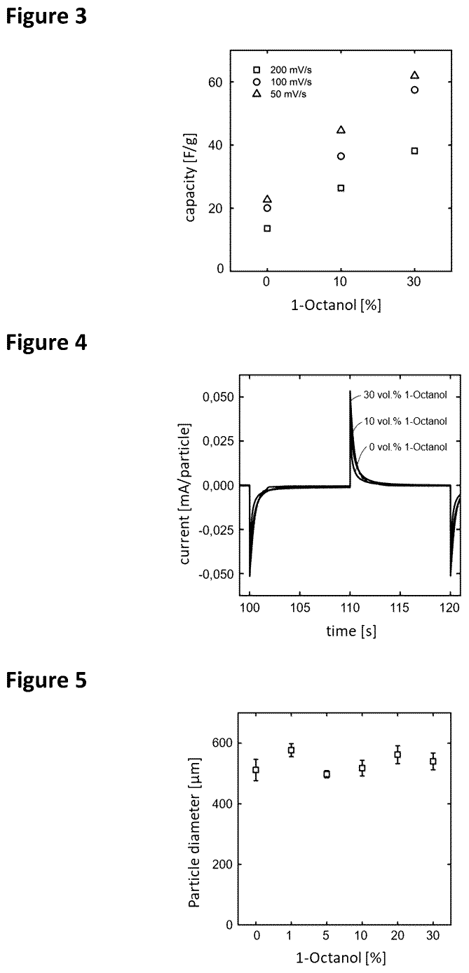

FIG. 3 the gravimetric capacity of PEDOT:PSS particles according to the invention as a function of porosity;

FIG. 4 the dependence of the redox kinetics of PEDOT:PSS particles according to the invention as a function of porosity;

FIG. 5 the dependence of the particle diameters of PEDOT:PSS particles according to the invention as a function of porosity;

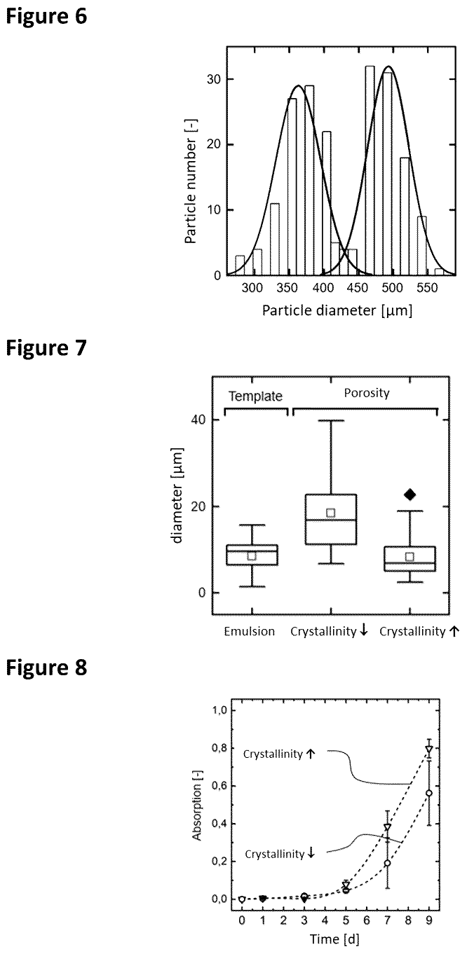

FIG. 6 the size distribution of PEDOT:PSS particles according to the invention prepared with a volume fraction of 30% of 1-octanol in the aqueous PEDOT:PSS mixture;

FIG. 7 the pore size distribution of PEDOT:PSS particles prepared according to the invention with a volume fraction of 30% 1-octanol in the aqueous PEDOT:PSS mixture;

FIG. 8 the proliferation of L929 cells on particles according to the invention as a function of time and as a function of the crystallinity of the support material;

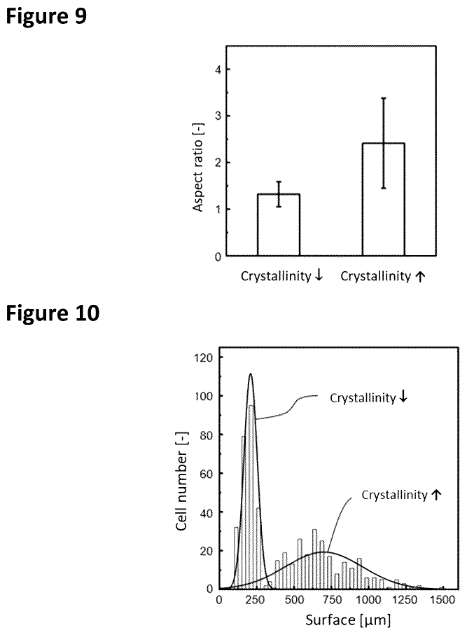

FIG. 9 the influence of crystallinity on the aspect ratio on particles of proliferating L929 cells according to the invention;

FIG. 10 the influence of the crystallinity of particles according to the invention on the propagation area of L929 cells.

FIG. 1 shows an FeSEM image of a porous PEDOT:PSS particle prepared according to the invention. The PEDOT:PSS particle was prepared with a 1-octanol volume fraction of 30% in the aqueous PEDOT:PSS mixture. Since PEDOT:PSS particles are hydrogels and thus collapse in anhydrous environments, the particle was freeze-dried prior to optical analysis.

FIG. 2 shows an FeSEM image of a porous PEDOT:PSS particle colonized with L929 mouse fibroblasts. Colonization of the microcarrier is shown after 4 days of cultivation at 37° C., 95% humidity and 5% CO₂. The culture medium was RPMI supplemented with 10% fetal calf serum and 1% penicillin-streptomycin. The inoculation concentration was 10,000 cells/cm². Since PEDOT:PSS particles are hydrogels and thus collapse in anhydrous environments, the particle was dried with an ethanol series (35, 50, 70, 100%) followed by treatment in hexamethyldisilazane (HMDS) prior to optical analysis.

FIG. 3 shows the gravimetric electrical capacitance of the PEDOT:PSS particles as a function of the 1-octanol volume fraction in the 1-octanol PEDOT:PSS emulsion and as a function of the sampling rate. Higher 1-octanol fractions denote a larger proportion of pore volume to particle volume (porosity) and thus a higher specific surface area. Electrical capacitances were determined from cyclic voltametry measurements in a 3-electrode setup as a function of scan rate. Since the specific surface area of the particles is directly proportional to the particle capacitance, more porous particles show a higher gravimetric capacitance. Higher scan rates result in smaller capacitances because the faster cycling of voltages means that the complete surface area of the particle contributing to the capacitance is not used.

FIG. 4 shows the current curve as a function of time. The redox kinetics of the PEDOT:PSS particles were recorded by chronoamperometry measurements as a function of the volume fraction of 1-octanol and thus of the porosity in a 3-electrode setup. The reaction time of the particles shortens with increasing porosity, although the charge density increases with increasing porosity. The shortened reaction time is attributed to the high specific surface area as well as the good accessibility of the pore system, which allows for fast redox kinetics. The measurements were performed over 9 cycles, with only one cycle shown in the diagram.

FIG. 5 shows the average particle diameter as a function of the 1-octanol volume fraction in the 1-octanol PEDOT:PSS emulsion as a measure of particle porosity. All particles shown in the diagram were prepared with a 1-octanol flow rate (continuous phase) of 0.5 mL/min and a PEDOT:PSS dispersion/emulsion flow rate of 0.05 mL/min The particles have a particle diameter of approximately 540 pm regardless of particle porosity. The small standard deviation in particle diameter likely stems from the fact that the droplets in the co-flow device are produced monodisperse Smaller variations in particle diameter come from a very small difference in separation kinetics of the protective 1-octanol shell in the coagulation bath.

FIG. 6 shows the size distribution of high (left) and low (right) crystalline PEDOT:PSS particles prepared with a volume fraction of 1-octanol of 30% in the aqueous PEDOT:PSS mixture. A rather narrow particle size distribution is obtained for both cases.

FIG. 7 shows the porogen and pore size distributions for high and low crystallinity porous PEDOT:PSS particles prepared with a volume fraction of 1-octanol of 30%. Most of the pores show a size between 15 and 20 μm. More than 90% of the pores show a pore size between 10 and 30 μm.

FIGS. 8-10 show the results in cell colonization of particles according to the invention. For the culture experiments, spherical PEDOT:PSS particles were prepared from a 30 vol % 1-octanol in PEDOT:PSS (1.1-1.3 wt %) emulsion, which was brought to droplet breakup in a continuous 1-octanol phase. The emulsion was obtained via an ultrasonic homogenizer (Hierschler UP100H). Both phases were added together via a syringe pump (Chemyx, Nexus Fusion 4000) at flow rates of 0.05 and 0.5 ml/min, respectively. The coagulation bath consisted of 5 vol % sulfuric acid in isopropanol unless otherwise specified.

FIG. 8 shows the results of the proliferation of L929 cells on particles according to the invention as a function of time and as a function of the crystallinity of the support material. Using different coagulation with different amounts of acid, porous particles with different degree of crystallinity were produced. The low-crystalline particles were coagulated with 5 vol % and the high-crystalline particles were coagulated with 95 vol % sulfuric acid. Particles with different mechanical properties are obtained. The properties result as follows:

| | E-modulus | Breaking load/ | Elongation at |
|---|---|---|---|
| Crystallinity | in MPa | kPa | break % |
| High | 0.07 | 28 (+/−13) | 36 (+/−6) |
| Low | 9.85 | 626 (+/−32) | 13 (+/−6) |

The different mechanical properties are a strong indication that the structure of the two samples, despite having the same composition, is different. These different properties of the spherical particles also lead to changes in the biological properties. FIG. 8 shows the results of cell proliferation of L929 mousefibroblasts with a seeding density of 2,600 cells/cm², N=5 on pure PEDOT:PSS microcarriers, where viability was quantified using an XTT proliferation assay. It can be clearly seen that the crystallinity of the support material has an effect on cell proliferation. Proliferation from day 5 is significantly higher on high crystallinity samples (triangles) than on low crystallinity samples (circles).

FIG. 9 shows the influence of crystallinity on the aspect ratio on particles of proliferating L929 cells according to the invention. The degree of crystallinity of the particles also seems to have an influence on the achievable morphology of the cell lines used. By means of confocal microscopy, DAPI/phalloidin-stained L929 cells can be assessed morphologically. One way to visualize cell symmetry is to determine the aspect ratio of the L929 cells. Different cell morphologies are found on low and high crystallinity particles, with more rounded cell morphologies developing on low crystallinity particles and more elongated cell morphologies developing on high crystallinity particles. The seeding density was 2,600 cells/cm², the measurement was performed on 250 cells on the second day.

FIG. 10 shows the influence of the crystallinity of particles according to the invention on the propagation area of L929 cells. The different degrees of crystallinity of the particles were obtained via different coagulation treatment of spherical particles. It can be seen that a single L929 cell colonizes a significantly larger area on crystalline particles. In contrast, the spread of cells on particles with low crystallinity is much more limited. Furthermore, it results that the cells on particles with low crystallinity probably proliferate deeper into the particle interior. The colonization density inside the particles, on the other hand, appears to be reduced in the case of highly crystalline particles.

1. Process for preparing poly(3,4ethylenedioxythiophene):polystyrenesulfonate (PEDOT:PSS) particles at least comprising the steps:
a) providing a mixture comprising poly(3,4-ethylenedioxythiophene) and polystyrene sulfonate in a solvent at least comprising water;
b) forming one or more PEDOT:PSS droplets by introducing the mixture from process step a) into an organic solvent A, wherein the aqueous PEDOT:PSS mixture forms the droplet interior and the organic solvent A forms the droplet exterior;
c) contacting the PEDOT:PSS droplets obtained from process step b) with a coagulating solution comprising a curing agent and at least one further solvent B, the density of the coagulating solution being greater than the density of the organic solvent A and less than the density of the aqueous poly(3,4-ethylenedioxythiophene) and polystyrene sulfonate mixture; with curing of the PEDOT:PSS droplets to PEDOT:PSS particles.

2. Process according to claim 1, wherein the organic solvent A is selected from the group consisting of branched or unbranched C5-C10 alkanes, branched or unbranched C5-C10 alcohols or mixtures of at least two solvents thereof.

3. Process according to claim 1, wherein the further solvent B is selected from the group consisting of branched or unbranched C1-C5 alcohols or mixtures of at least two solvents thereof.

4. Process according to claim 1, wherein the solvent A comprises octanol and the coagulating solution in process step c) comprises isopropanol as solvent B and sulfuric acid as curing agent.

5. Process according to claim 1, wherein the weight ratio of curing agent and solvent B in the coagulating solution, expressed as weight of curing agent divided by weight of solvent B, is greater than or equal to 0.005 and less than or equal to 0.2.

6. Process according to claim 1, wherein the PEDOT:PSS mixture in process step a) does not comprise any further mechanically solidifying substances.

7. Process according to claim 1, wherein the PEDOT:PSS mixture in process step a) comprises, in addition to water an organic solvent A as a further solvent component.

8. Poly(3,4-ethylenedioxythiophene)-polystyrenesulfonate particles, characterized in that the particles are spherical and do not contain any other mechanically solidifying substances in addition to PEDOT:PSS.

9. The particles according to claim 8, wherein the particles are porous and have a porosity greater than 0 volume % and less than or equal to 95 volume %.

10. The particles according to claim 8, wherein the particle has a modulus of elasticity greater than or equal to 0.05 MPa and less than or equal to 15 MPa.

11. The particles according to claim 8, wherein the particle is at least partially crystalline with Bragg reflections in an XRD spectrum at 4.3 (+−0.2) nm⁻¹ and 18.4 (+−0.2) nm⁻¹.

12. The particles according to claim 8, wherein the surface of the particle has a zeta potential of less than or equal to 0 mV.

13. Use of the particles according to claim 8, selected from the group consisting of cell culture microcarriers, suspension electrodes, switchable redox absorber material, catalyst supports, or combinations thereof.

14. Use according to claim 13, wherein the particles are used as cell culture microcarriers, wherein the surface of the particles is coated prior to cultivation with one or more molecules selected from the group consisting of poly-L-lysine, laminin, collagen, fibronectin, vitronectin or mixtures thereof.

15. Use according to claim 14, wherein the surface of the particles is first coated with poly-L-lysine and then with laminin.
